(19) United States
(12) Patent Application Publication
(10) Pub. No.: US 2005/0046603 A1
(43) Pub. Date: Mar. 3, 2005

(54) FAST DIGITAL DATA RECOVERY CIRCUIT

(76) Inventors: Andrew Chang, Hsin-Chu City (TW); Shyh-Jong Chen, Taipei City (TW)

Correspondence Address: (NAIPC) NORTH AMERICA INTERNATIONAL PATENT OFFICE, P.O. BOX 506, MERRIFIELD, VA, 22116, US

(21) Appl. No.: 10/708,948

(22) Filed: Apr. 2, 2004

(30) Foreign Application Priority Data
Sep. 3, 2003 (TW) 092124391

(51) Int. Cl. H03M 1/12

(52) U.S. Cl. 341/155

(57) ABSTRACT

A digital data recovery circuit for converting an input signal into a sliced signal includes a comparing device coupled with the input signal and a reference level signal for comparing the input signal with the reference level signal and generating the sliced signal according to the result of comparison, a phase-detecting, level-determining device coupled with the comparing device for detecting the phase at which the transition of the sliced signal occurs, based on a reference clock, and generating a digital level signal according to the result of detection, and a digital-to-analog converter (DAC) coupled with the phase-detecting, level-determining device for generating the reference level signal for the comparing device according to the digital level signal.

### BACKGROUND OF INVENTION

1. Field of the Invention

The invention relates to a digital data recovery circuit, and more particularly, to a digital data recovery circuit using a phase-detecting, level-determining device to detect the phase, and thereby to determine a reference level signal.

2. Description of the Prior Art

Digital data recovery circuit, which compares an analog input signal with a reference level signal to determine whether the binary value of the input signal represents “0” or “1”, i.e. to convert the analog input signal into a digital output signal, are widely used in transmission systems.

Please refer to FIG. 1 showing a block diagram of a conventional digital data recovery circuit 100. The digital data recovery circuit 100 has a comparator 120 and a low pass filter 140. The Xi1 is the signal input into the digital data recovery circuit 100. The comparator 120 compares the input signal Xi1 with a reference level signal Vc1 and outputs a sliced signal Xo1. The sliced signal Xo1 will be of a first binary value when the level of Xi1 is lower than the level of Vc1, and of a second binary value when the level of Xi1 is higher than the level of Vc1. As an example, the first binary value is “0” and the second binary value is “1.” In this case, that Xo1 is at “1” represents the input signal Xi1 has a higher level than Vc1, while that Xo1 is at “0” represents the input signal Xi1 has a lower level than Vc1.

Since the input signal Xi1 contains a direct current (DC) component, which usually varies in accordance with time, the reference level signal Vc1 must be able to be adapted to trace the DC component of the input signal Xi1 so that the comparator 120 can slice Xi1 into Xo1 correctly. In other words, Vc1 should be kept equivalent to the DC component of Xi1.

Therefore, in the prior art, the sliced signal Xo1 passes through the low pass filter 140 to generate the reference level signal Vc1 to be used as a feedback signal. After being processed by the low pass filter 140, Vc1 will gradually approach the DC component of Xi1. And when the DC component of Xi1 varies, Vc1 will vary accordingly. The closer Vc1 is to Xi1, the more accurately Xo1 represents the “0”/“1” inside the input signal Xi1.

Please refer to FIG. 2 showing a block diagram of another conventional digital data recovery circuit 200. The digital data recovery circuit 200 includes a comparator 220, an up/down counter (UDC) 240, and a digital-to-analog converter (DAC) 260. The Xi2 is the signal input into the digital data recovery circuit 200. The comparator 220 compares the input signal Xi2 with a reference level signal Vc2 and outputs a sliced signal Xo2. The sliced signal Xo2 will be of a first binary value when the level of Xi2 is lower than the level of Vc2, and of a second binary value when the level of Xi2 is higher than the level of Vc2.

Without loss of generality, assume that the first binary value is “0” and the second binary value is “1”. In the case of the sliced signal Xo2 being “0”, whenever a clock K2 transits upwards (from “0”to “1”), the counter value DL2 output by the UDC 240 is decreased by one. In the case of the sliced signal Xo2 being “1”, whenever a clock K2 transits upwards, the counter value DL2 output by the UDC 240 is increased by one. In a result, the reference level signal Vc2 output by the DAC 260 will gradually approach a DC component of Xi2. And when the DC component of Xi2 varies, Vc2 will be adapted to trace the variation of Xi2. The closer Vc2 is to Xi2, the more accurately the sliced signal Xo2 generated by the comparator 220 represents Xi2.

The problem of the prior art is that the reference level signal requires a specific amount time to approach the DC component of the input signal, meaning that before the approach, the sliced signal output by the comparator may not effectively represent the binary values of the input signals.

Briefly, the digital data recovery circuit in the prior art requires a specific approach time to allow the reference level signal to approach the DC component of the input signal, in order to have the sliced signal represent the binary value of the input signals accurately.

### SUMMARY OF INVENTION

It is therefore a primary objective of the claimed invention to provide a digital data recovery circuit capable of adjusting a reference level signal to approach a DC component of an input signal, in order to solve the problem mentioned above.

Briefly, a digital data recovery circuit for converting an input signal into a sliced signal includes a comparing device coupled with the input signal and a reference level signal for comparing the input signal with the reference level signal and generating the sliced signal according to the result of comparison, a phase-detecting, level-determining device coupled with the comparing device for detecting the phase at which the transition of the sliced signal occurs, based on a reference clock, and generating a digital level signal according to the result of detection, and a digital-to-analog converter (DAC) coupled with the phase-detecting, level-determining device for generating the reference level signal for the comparing device according to the digital level signal.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a block diagram of a conventional digital data recovery circuit.

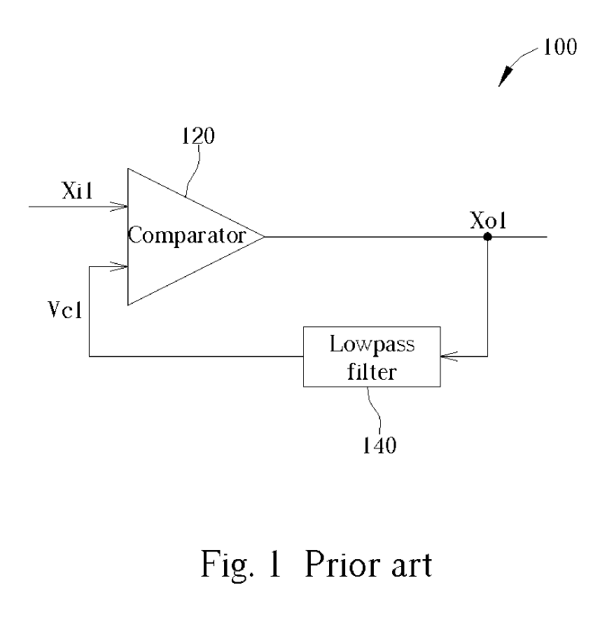

FIG. 2 is a block diagram of another conventional digital data recovery circuit.

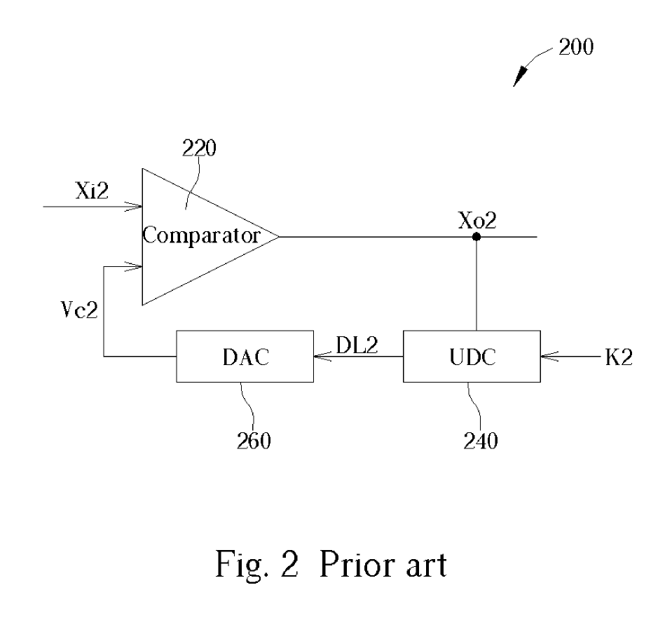

FIG. 3 is a block diagram of a digital data recovery circuit according to the present invention.

FIG. 4 is a timing diagram of the system in FIG. 3.

FIG. 5 is a circuit diagram of the phase detector.

FIG. 6 is a timing diagram of each clock and sliced signal.

FIG. 7 is a circuit diagram of the transition phase detecting device.

### DETAILED DESCRIPTION

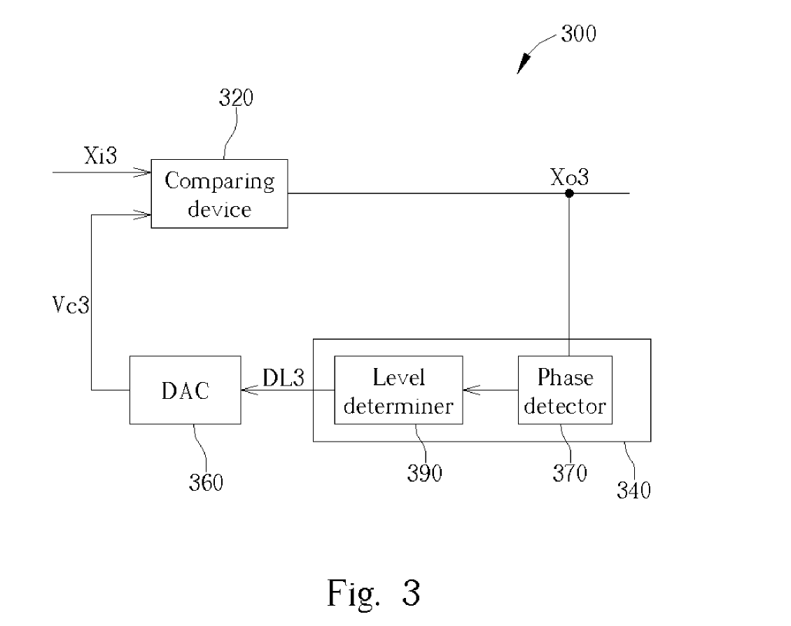

Please refer to FIG. 3 showing a block diagram of a digital data recovery circuit 300 according to the present invention, which converts an analog input signal Xi3 into a digital sliced signal Xo3. The data recovery circuit 300 includes a comparing device 320 coupled with the input signal Xi3 and a reference level signal Vc3 for comparing Xi3 with Vc3 to generate the sliced signal Xo3, a phase-detecting, level-determining device 340 coupled with the comparing device 320 for detecting the phase at which the transition of Xo3 occurs, according to a reference clock CLK (not shown in FIG. 3. The frequency of CLK is equal to the bit rate of Xi3.), and thereby generating a corresponding digital level signal DL3, and a DAC 360 coupled with the phase-detecting level-determining device 340 and the comparing device 320 for generating the reference level signal Vc3 according to the digital level signal DL3 for the comparing device 320. Please notice that the digital sliced signal Xo3 generated by the comparing device 320 can be a single bit or a plurality of bits. For a clearer description, a single bit Xo3 is described in the followings.

In the case of the level of the input signal Xi3 being lower than the level of the reference level signal Vc3, the sliced signal Xo3 output by the comparing device has a first binary value, and in the case of the level of the input signal Xi3 being higher than the level of the reference level signal Vc3, the sliced signal Xo3 output by the comparing device 320 has a second binary value. For a clearer description, assume that the first binary value is “0” and the second binary value is “1.” Physically, the value “0” of Xo3 corresponds to a first voltage level V1; while the value “1” corresponds to a second voltage level V2, and V2>V1. Please notice that the comparing device can be a comparator, a one-bit analog-to-digital converter (ADC), a multi-bit ADC or a partial-response maximum likelihood circuit.

The sliced signal Xo3 output by the comparing device 320 is a square wave switching between the first level V1 and the second level V2. The closer the level of the reference level signal Vc3 is to a DC component of the input signal Xi3, the more accurately Xo3 represents a signal component of Xi3. In order to achieve to goal, the phase-detecting, level-determining device 340 and the DAC 360 must cooperate with each other to generate an accurate reference level signal Vc3 for the comparing device 320.

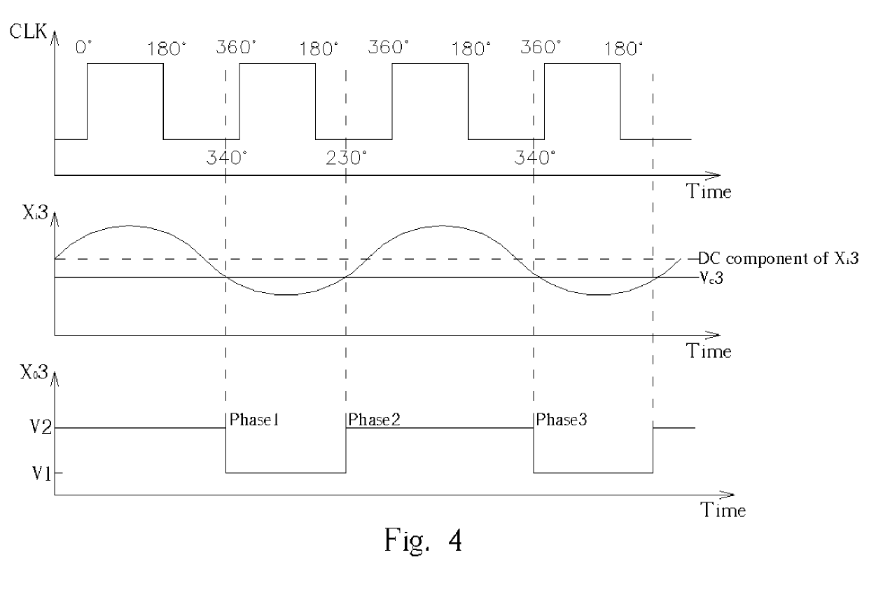

Please refer to FIG. 4 showing a timing diagram, as an example, of the system in FIG. 3. The period of the reference clock signal CLK has been configured in advance to match the duration of the data bits carried by Xo3. In this diagram, the level of the reference level signal Vc3 is initially lower than the DC component of the input signal Xi3; thus the duty cycle of the sliced signal Xo3 output by the comparing device 320 is higher than 50%, i.e. the period during which Xo3 is kept at the first level V1 is shorter than the period of the reference clock CLK, or in other words, the period during which Xo3 is kept at the second level V2 is longer than the period of the reference clock signal CLK.

The situation that the duty cycle of the sliced signal Xo3 is larger or less than 50% can be realized by examining the transitions of Xo3. For instance in FIG. 4, based on the reference clock CLK, Xo3 transits at PHASE 1, which is 340+ as shown in FIG. 4, from the second level V2 to the first level V1, then transits at PHASE 2, which is 230° as shown in FIG. 4, from the first level V1 to the second level V2, and then transits at PHASE 3, which is 340° as shown in FIG. 4, from the second level V2 to the first level V1. Note that all the phase mentioned here is a phase value related to the reference clock signal CLK, and the phase recurs once every 360 degrees, thus the phase over 360 degrees must be converted between 0 degree and 360 degrees. It is observed that since the period during which Xo3 is kept at V1 will be less than the period of the reference clock CLK (or less than n times the period of the reference clock CLK, wherein n is an integer), PHASE 2−PHASE 1 is a negative value (e.g. PHASE 2−PHASE 1=110°). It is observed that since the period during which Xo3 is kept at V2 is longer than the period of the reference clock CLK (or more than n times the period of the reference clock CLK, wherein n is an integer), PHASE 3−PHASE 2 is a positive value (e.g. PHASE 2−PHASE 1=110°).

In result, based on the reference clock CLK whose frequency is the same as the bit rate of the input signal Xi3, by detecting the phase during the transition of the sliced signal Xo3, the duty cycle of Xo3 can be known. If the duty cycle is higher than 50%, the level of the reference level signal Vc3 should be raised, and if the duty cycle is lower than 50%, the level of the reference level signal Vc3 should be lowered down.

As shown in FIG. 3, the phase-detecting, level-determining device 340 includes a phase detector 370 coupled with the comparing device 320 for detecting the phase at which the sliced signal Xo3 transits from the first binary value to the second binary value (i.e. the level transits from the first level V1 to the second level V2), and detecting the phase at which the sliced signal Xo3 transits from the second binary value to the first binary value (i.e. the level transits from the second level V2 to the first level V1), based on the reference clock CLK, and a level determiner 390 coupled with the phase detector for generating digital level signals DL3 corresponding to the result of detection.

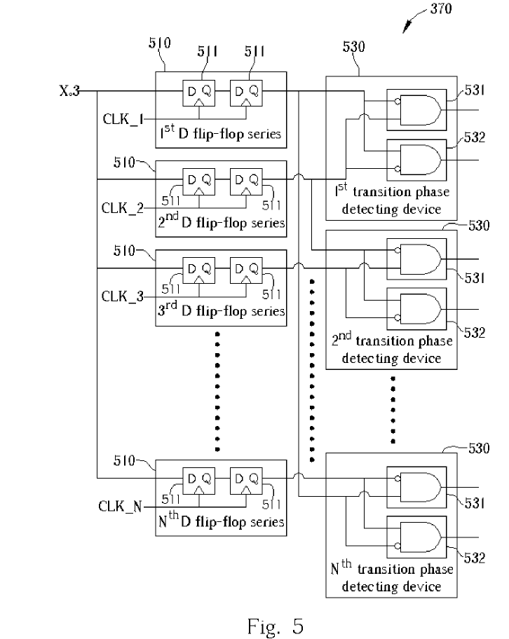

Please refer to FIG. 5 showing a circuit diagram of the phase detector 370. Some symbols are introduced here: N is a predetermined positive integer, K is a positive integer between 1 and N, and L is a positive integer between 1 and N-1. The phase detector 370 includes N number of delay flip-flop series (D flip-flop series) 510 and N number of transition phase detecting devices 530. Each D flip-flop series 510 has an input end, a clock input end, and an output end. The input end of each D flip-flop series 510 is coupled with the sliced signal Xo3, and the clock input end of the K^{th} D flip-flop series 510 is coupled with a clock signal CLK_K generated by delaying the reference clock CLK for K/N period. Each transition phase detecting device 530 has a first input end, a second input end, a first output end, and a second output end. The first input end of the L^{th} transition phase detecting device 530 is coupled with the output end of the L^{th} D flip-flop series 510, and the second input end is coupled with the output end of the L+1^{th} D flip-flop series 510. The first input end of the N^{th} transition phase detecting device 530 is coupled with the output end of the N^{th} D flip-flop series 510, and the second input end is coupled with the output end of the 1^{st} D flip-flop series 510.

Please notice that in the present embodiment, each D flip-flop series 510 has two D flip-flops 511; however, the use of one or more than one D flip-flop 511 are also covered by the present invention. The reason for using more than one flip-flop is to ensure signals output by the D flip-flop series 510 are accurate (Metastability can be prevented by using two flip-flops. Metastability occurs when the transition edge and the clock edge of Xo3 are too close to each other. Once metastability occurs, the Q value of the flip-flop may be unstable; this problem can be simply solved by cascading more than one flip-flop). Based on the reference clock CLK, the phase of CLK_K is K/N (in this case the phase is represented by the period; it will be 360*K/N when represented by degree), thus CLK_N is just the reference clock CLK itself (thus no need to be delayed).

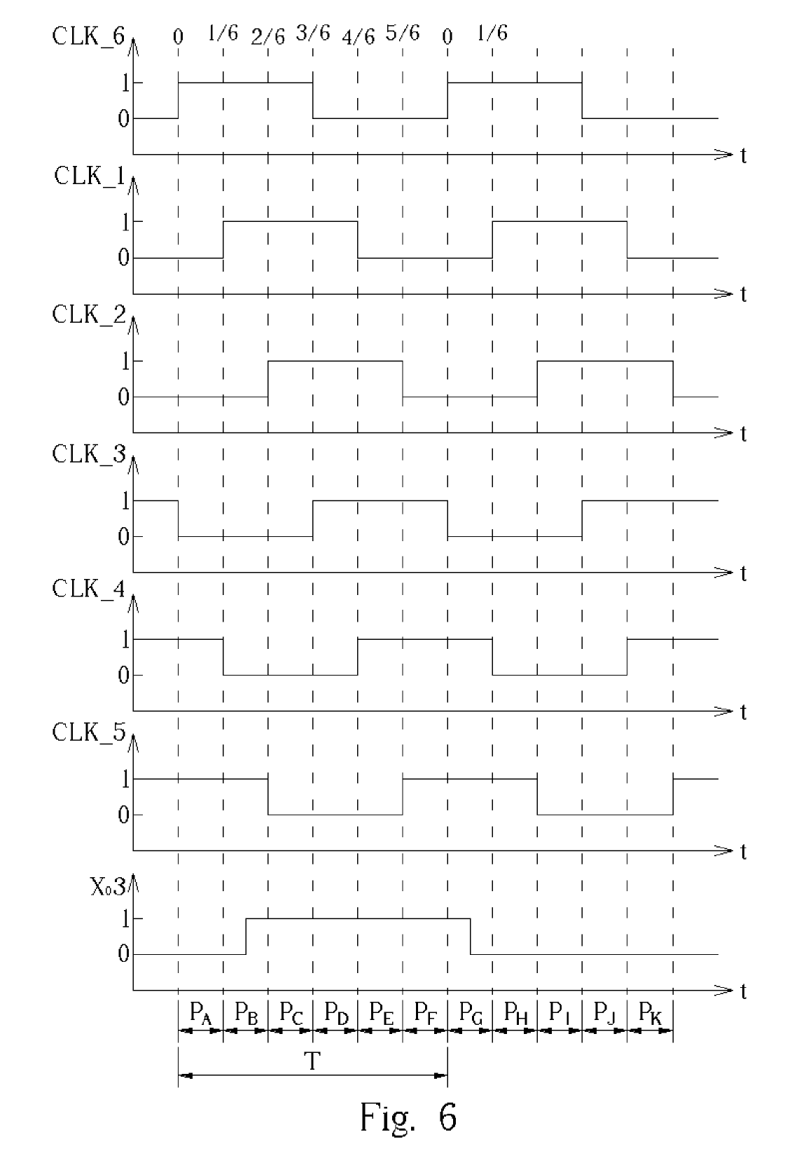

For a clearer description of the phase detector 370 in FIG. 5, please refer to FIG. 6 showing a timing diagram of each clock CLK_K, K=1, . . . ,N and an exemplary sliced signal Xo3 in the case of N=6. Note that the clock CLK_K represents just the original reference clock. That N=6 implies that the period T of the clock CLK is equally divided into 6 sub-periods, as shown in the FIG. 6. Taking the beginning time of the period as a reference, the sub-periods start at time points of 0, 1/6, 2/6, 3/6, 4/6, 5/6, respectively. Notably, these time points have been normalized by T for clear notation. Since each of these time points can also be used or represent the phase at which the corresponding sub-period falls. In the following, we will express the phase in this way. Suppose the level of the reference level signal Vc3 is higher than the DC component of the input signal Xi3, the time duration during which Xo3 is kept at the second level (i.e. “1”) would be less than the period of the reference clock CLK. Taking the CLK as a reference, suppose that the phase at which Xo3 transits upwards (from “0” to “1”) falls between 1/6 and 2/6, and the phase at which Xo3 transits downwards (from “1” to “0”) falls between 0 (i.e. 6/6) and 1/6. As well known, in the operation of the flip-flops 511, the signal from the input end will be transmitted to the output end only when signal at the clock input end transits from “0” to “1”. Therefore, the output end of the second D flip-flop series 510 will become “1” firstly, and the output ends of the third, fourth, fifth, and sixth D flip-flop series 510 will also become “1” in sequence. On the other hand, since Xo3 transits downwards between phase 0 and 1/6, the output end of the first D flip-flop series 510 will become “0” firstly, and the output ends of the second, third, fourth, and fifth D flip-flop series 510 will become “0” in sequence. Actually, since the phase of the sliced signal Xo3 is between 1/6 and 2/6 in upward transition, the output ends of the second, third, fourth, fifth, and sixth D flip-flop series 510 becomes “1” in sequence, and since the phase of the sliced signal Xo3 is between 0 and 1/6 in downward transition, the output ends of the second, third, fourth, and fifth D flip-flop series 510 becomes “0” in sequence. In result, the output of each D flip-flop series 510 will extract the signal level of the sliced signal Xo3 at specified phase. Therefore, having the output results of the D flip-flop series 510, it is enough to tell which subperiod the transition of the sliced signal Xo3 occurs at. Accordingly, the value of the digital level signal DL3 can be determined, as will be shown later.

A plurality of transition phase detecting devices are employed to detect the phase at which the phase transition of the sliced signal Xo3 occurs, based on the output results of the N number of D flip-flop series. Let R be an integer between 1 an N. An R^{th} transition phase detecting device 530 includes an upward transition detecting unit 531 and a downward transition detecting unit 532. The upward transition detecting unit 531 has a first input end coupled with a first input end of the R^{th} transition phase detecting device 530, a second input end coupled with a second input end of the R^{th} transition phase detecting device 530, and an output end used as a first output end of the R^{th} transition phase detecting device 530.The downward transition detecting unit 532 has a first input end coupled with the first input end of the R^{th} transition phase detecting device 530, a second input end coupled with the second input end of the R^{th} transition phase detecting device 530, and an output end used as a second output end of the R^{th} transition phase detecting device 530.

Based on the block diagrams of the transition phase detecting devices 530 shown in FIG. 5, it can be found that either when the first and second input values are both “0” or “1”, the first and second output values will be “0”. Moreover, when the first input value is “0” and the second input value is “1”, the first output value will be “1” and the second output value will be “0.” And, when the first input value is “1” and the second input value is “0”, the first output value will be “0” and the second output value will be “1”. In such a way, the upward transition detecting unit 531 is capable of detecting the upward transition of the sliced signal Xo3, and the downward transition detecting unit 532 is capable of detecting the downward transition of the sliced signal Xo3. Now please refer again the example shown in FIG. 6. Initially, the outputs of each D flip-flop series 510 are set to be “0”. During the period P_{A}, the sixth D flip-flop series 510 will be triggered by the clock CLK_6 and latch the signal level, which is “0” in the example, of the sliced signal Xo3 at the starting time instant of the period P_{A}. The outputs of the other D flip-flop series 510 will remain since their associated clock signals does not trigger them to update their outputs. During the period P_{B}, the first D flip-flop series 510 will be triggered by the clock CLK_1 and latch the signal level, which is “0” in the example, of the sliced signal Xo3 at the starting time instant of the period P_{B}. Similarly, during the period P_{C}, the second D flip-flop series 510 will output “1”. As can be seen, the output “0” of the first D flip-flop series 510 and the output “1” of the second D flip-flop series 510 will remain during the next periods P_{D}, P_{E}, and P_{F}.

On the other hand, during the period P_{G}, the sixth D flip-flop series 510 will be triggered by the clock CLK_6 and latch the signal level, which is “1” in the example, of the sliced signal Xo3 at the starting time instant of the period P_{G}. The outputs of the other D flip-flop series 510 will remain since their associated clock signals does not trigger them to update their outputs. During the period P_{H}, the first D flip-flop series 510 will be triggered by the clock CLK_1 and latch the signal level, which is “0” in the example, of the sliced signal Xo3 at the starting time instant of the period P_{H}. As can be seen, the output “1” of the sixth D flip-flop series 510 and the output “0” of the first D flip-flop series 510 will remain during the next periods P_{I}, P_{J}, and P_{K}.

Let A and B are both positive integers between 1 and N. Generally speaking, when the Xo3 transits from “0” to “1” at a phase between (A-1)/N and A/N, the upward transition detecting unit 531 of the A^{th} transition phase detecting device 530 will have its output to be “1” for a period longer than 1.T/N, where T is the period of the reference clock CLK. Note that it is a transient phenomenon and will not be regarded as an actual phase transition event if the output “1” of the transition phase detecting device 530 merely appears during a period of 1.T/N. On the other hand, when the Xo3 transits from “1” to “0” at a phase between (B-1)/N and B/N, the downward transition detecting unit 532 of the B^{th} transition phase detecting device 530 will have its output to be “1” for a period longer than 1.T/N.

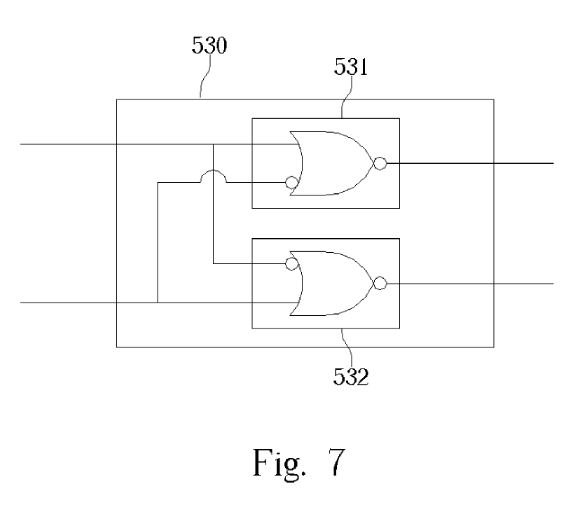

The upward transition detecting unit 531 and the downward transition detecting unit 532 in FIG. 5 are both composed of an inverter and an AND gate; however, another composition is possible. Please refer to FIG. 7 showing a circuit diagram of another embodiment of the transition phase detecting device 530. The upward transition detecting unit 531 and the downward transition detecting unit 532 in FIG. 7 are composed of an inverter and an OR gate, which is well known by the person skilled in the art to recognize that the transition phase detecting devices 530 shown in FIG. 5 and FIG. 6 perform the identical function, and thus a further description is hereby omitted. Furthermore, it is also obvious that the upward transition detecting units 531 (the downward transition detecting units 532) shown in FIG. 5 and FIG. 7 are equivalent to each other and therefore exchangeable for implementation.

In the embodiment mentioned above, if the value of the reference level signal Vc3 is accurate, the phase of the sliced signal Xo3 in downward transition differs from that in upward transition for n periods, wherein n is an integer, i.e. the remainder of the two phases is 0. However in this embodiment, the phase of Xo3 in upward transition is detected by the phase detector 370 to be between 1/6 and 2/6, while that in downward transition is between 0 and 1/16, i.e. the remainder of the phase in downward transition minus that in upward transition is negative (0-1/6 or 1/6-2/6). The result of detection shows the time Xo3 is kept at the second level V2 is shorter, i.e. the level of the reference level signal Vc3 is higher than the DC component of the input signal Xi3, so that the level of Vc3 should be adjusted to a lower level. If the remainder of the phase in downward transition minus that in upward transition is positive, the result of detection shows the time Xo3 kept at the first level V1 is shorter, i.e. the level of the reference level signal Vc3 is lower than the DC component of the input signal Xi3, so that the level of Vc3 should be adjusted to a higher level. Of course, the remainder of the phase in upward transition minus that in downward transition can be also used for the adjustment. If the remainder of the phase in upward transition minus that in downward transition is positive, the level of Vc3 should be adjusted to a lower level, and if the remainder of the phase in upward transition minus that in downward transition is negative, the level of Vc3 should be adjusted to a higher level. Of course, the larger the number N in the D flip-flop series 510 and transition phase detecting devices 530, the more accurate the transition phase detected by the phase detector 370.

After the phase detector 370 in FIG. 3 detects the transition phase of the sliced signal, the level determiner 390 can determine the value of the digital level signal according to the result of detection. Generally, when the result of detection shows the level of the reference level signal Vc3 is lower, the level determiner 390 outputs a higher digital level signal DL3, and when the result of detection shows the level of the reference level signal Vc3 is higher, the level determiner 390 outputs a lower digital level signal DL3. The level determiner 390 can optimize DL3, e.g. if the remainder of the phase in downward transition minus that in upward transition is 3/N, subtract 5 from DL3; if the remainder of the phase in downward transition minus that in upward transition is +1/N, add 2 to DL3. Of course, the more accurate the parameters of the design, the more accurate the system and the more rapidly Vc3 approaches to the DC component of the input signal Xi3.

Another approach for adjusting the digital level signal DL3 is disclosed as follows. If the phase of the downward transition minus that of the upward transition is negative, the level determiner 390 decrease DL3 by a predetermined amount. On the other hand, if the phase of the downward transition minus that of the upward transition is positive, the level determiner 390 increases DL3 by a predetermined amount. However, in such kind of approach, the level of the reference level signal Vc cannot trace the DC component of the input signal Xi3 very rapidly.

Following the operations mentioned above, a proper digital level signal DL3 is determined under the cooperation of the phase detector 370 and the level determiner 390.The DAC 360 then converts DL3 into the reference level signal Vc3 so that the comparing device 320 can slice the signal component in the input signal Xi3 accordingly.

Please notice that in addition to the phase detector 370 being composed of logic gates in FIG. 5, the phase detector 370 in FIG. 3 can be also composed of a delay lock loop (DLL). Also, the DAC 360 in FIG. 3 can be a voltage source for generating the reference level signal Vc3, a current source generating current signals to be converted into Vc3 by an external circuit, or a control circuit for directly controlling the bit value of the sliced signal Xo3 output by the comparing device 320.

In contrast to the prior art, the digital data recovery circuit according to the present invention determines how to adjust the level of the reference level signal by detecting the phase so that the reference level signal can approach to the DC component of the input signal rapidly.

Those skilled in the art will readily observe that numerous modifications and alterations of the device may be made while retaining the teachings of the invention. Accordingly, the above disclosure should be construed as limited only by the metes and bounds of the appended claims.

1. A digital data recovery circuit for converting an input signal into a sliced signal comprising:
a comparing device coupled with the input signal and a reference level signal for comparing the input signal with the reference level signal and generating the sliced signal according to the result of comparison;
a phase-detecting, level-determining device coupled with the comparing device for detecting the phase at which the transition of the sliced signal occurs, based on a reference clock, and generating a digital level signal according to the result of detection; and
a digital-to-analog converter (DAC) coupled with the phase-detecting, level-determining device for generating the reference level signal for the comparing device according to the digital level signal.

2. The digital data recovery circuit of claim 1 wherein the phase-detecting, level-determining device further comprises:
a phase detector coupled with the comparing device for detecting the phase of the sliced signal transiting from a first binary value to a second binary value, and the phase of the sliced signal transiting from the second binary value to the first binary value, based on the reference clock; and
a level determiner coupled with the phase detector for generating the digital level signal according to the result of detection.

3. The digital data recovery circuit of claim 2 wherein the phase detector comprises:
N flip-flop series wherein each of the flip-flop series has an input end, a clock input end, and an output end, and each input end of the flip-flop series is coupled with the sliced signal with the clock input end of a K^{th} flip-flop series being coupled with the signal generated by delaying the reference clock for K/N period; and
N transition phase detecting devices wherein each transition phase detecting device has a first input end, a second input end, a first output end, and a second output end; the first input end of an L^{th} transition phase detecting device is coupled with the output end of the L^{th} flip-flop series, the second input end of the L^{th} transition phase detecting device coupled with the output end of an L+1^{th} flip-flop series, the first input end of an N^{th} transition phase detecting device coupled with the output end of an N^{th} flip-flop series, and the second input end of the N^{th} transition phase detecting device coupled with the output end of the first flip-flop series, wherein N is a positive integer, K is a positive integer between 1 and N, and L is a positive integer between 1 and N-1.

4. The digital data recovery circuit of claim 3 wherein the K^{th} flip-flop series comprises M cascaded flip-flops, and the clock input end of each flip-flop is coupled with the clock input end of the K^{th} flip-flop series, the input end of a first flip-flop is used as the input end of the K^{th} flip-flop series, the output end of an M^{th} flip-flop is used as the output end of the K^{th} flip-flop series, and when M is larger than 1, the output end of a P^{th} flip-flop is coupled with the input end of a P+1^{th} flip-flop where M is a positive integer and P is a positive integer between 1 and M-1.

5. The digital data recovery circuit of claim 3 wherein an R^{th} transition phase detecting device comprises:
an upward transition detecting unit comprising a first input end coupled with a first input end of the R^{th} transition phase detecting device, a second input end coupled with a second input end of the R^{th} transition phase detecting device, and an output end used as a first output end of the R^{th} transition phase detecting device; and an downward transition detecting unit comprising a first input end coupled with a first input end of the R^{th} transition phase detecting device, a second input end coupled with a second input end of the R^{th} transition phase detecting device, and an output end used as a second output end of the R^{th} transition phase detecting device, wherein R is a positive integer between 1 and N.

6. The digital data recovery circuit of claim 5 wherein the upward transition detecting unit of the R^{th} transition phase detecting device comprises:
a first inverter with its input end used as the first input end of the upward transition detecting unit; and
a first AND gate with its input end coupled with an output end of the first inverter, another input end used as the second input end of the upward transition detecting unit, and an output end used as the output end of the upward transition detecting unit.

7. The digital data recovery circuit of claim 5 wherein the downward transition detecting unit of the R^{th} transition phase detecting device comprises:
a second inverter with its input end used as the second input end of the downward transition detecting unit; and
a second AND gate with its input end coupled with an output end of the second inverter, another input end used as the first input end of the downward transition detecting unit, and an output end used as the output end of the downward transition detecting unit.

8. The digital data recovery circuit of claim 5 wherein the upward transition detecting unit of the R^{th} transition phase detecting device comprises:
a first inverter with its input end used as the second input end of the upward transition detecting unit;
a first OR gate with its input end coupled with an output end of the first inverter and another input end used as the first input end of the upward transition detecting unit; and
a second inverter with its input end coupled with an output end of the first OR gate, and an output end used as the output end of the upward transition detecting unit.

9. The digital data recovery circuit of claim 5 wherein the downward transition detecting unit of the R^{th} transition phase detecting device comprises:
a third inverter with its input end used as the first input end of the downward transition detecting unit;
a second OR gate with its input end coupled with an output end of the third inverter and another input end used as the second input end of the downward transition detecting unit; and
a fourth inverter with its input end coupled with an output end of the second OR gate, and an output end used as the output end of the downward transition detecting unit.

10. The digital data recovery circuit of claim 2 wherein the phase detector is in a delay locked loop.

11. The digital data recovery circuit of claim 1 wherein the comparing device is a comparator generating the sliced signal having the first binary value when the level of the input signal is lower than the level of the reference level signal and generating the sliced signal having the second binary value when the level of the input signal is higher than the level of the reference level signal.

12. The digital data recovery circuit of claim 1 wherein the comparing device is an one-bit analog-to-digital converter (ADC) generating the sliced signal having the first binary value when the level of the input signal is lower than the level of the reference level signal and generating the sliced signal having the second binary value when the level of the input signal is higher than the level of the reference level signal.

13. The digital data recovery circuit of claim 1 wherein the comparing device is an ADC generating the sliced signal with bit values from 1 to N according to the relationship between the input signal and the reference level signal.

14. The digital data recovery circuit of claim 1 wherein the comparing device is a partial-response maximum likelihood circuit generating the sliced signal having the first binary value when the level of the input signal is lower than the level of the reference level signal and generating the sliced signal having the second binary value when the level of the input signal is higher than the level of the reference level signal.

15. The digital data recovery circuit of claim 1 wherein the DAC is a voltage source for providing a reference level required by the comparing device.

16. The digital data recovery circuit of claim 1 wherein the DAC is a current source for providing a reference level required by the comparing device converted by an external circuit from a current generated by the DAC.

17. The digital data recovery circuit of claim 1 wherein the DAC is a control circuit for directly controlling the bit value of the sliced signal output by the comparing device.
